(19) United States
(12) Patent Application Publication
(10) Pub. No.: US 2026/0079581 A1
(43) Pub. Date: Mar. 19, 2026

(54) TACTILE DISPLAY APPARATUS WITH TACTILE TRANSFER DEVICES OF ADJUSTABLE HEIGHT AND LIGHT-EMITTING DEVICE REGIONS

(71) Applicants: SAMSUNG ELECTRONICS CO., LTD., Suwon-si (KR); RESEARCH & BUSINESS FOUNDATION SUNGKYUNKWAN UNIVERSITY, Suwon-si (KR)

(72) Inventors: Kwangdon Kim, Suwon-si (KR); Byeungwoo Jeon, Suwon-si (KR); Muho Cheon, Suwon-si (KR); Jaelin Lee, Suwon-si (KR); Hyunki Jeong, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 19/323,626

(22) Filed: Sep. 9, 2025

Related U.S. Application Data
(63) Continuation of application No. PCT/KR2024/095161, filed on Feb. 15, 2024.

(30) Foreign Application Priority Data
Mar. 10, 2023 (KR) 10-2023-0031882

(51) Int. Cl. G06F 3/01; H10H 29/855

(52) U.S. Cl. CPC G06F 3/016; H10H 29/855

(57) ABSTRACT

A tactile display apparatus includes a display substrate with a plurality of pixels, each having a light-emitting device region with at least one light-emitting device operating based on image information; a plurality of tactile transfer devices positioned on the display substrate with adjustable height based on control signals; and at least one lens mounted on the light-emitting device region. The tactile transfer devices are arranged not to block light from the light-emitting device when controlled to maximum height. The tactile transfer devices may have origami structures for height adjustment through folding or unfolding. Optical conditions are satisfied to ensure proper light transmission, with lens positioning based on focal length relationships. The apparatus may include red, green, and blue light-emitting devices with corresponding lenses, and meta lenses based on nanostructures.

### CROSS-REFERENCE TO RELATED APPLICATION

This application is a by-pass continuation application of International Application No. PCT/KR2024/095161, filed on Feb. 15, 2024, which is based on and claims priority to Korean Patent Application No. 10-2023-0031882 filed on Mar. 10, 2023, in the Korean Patent Office, the disclosures of which are incorporated by reference herein in their entireties.

### 1. FIELD

The present disclosure relates to a tactile display apparatus having height adjustable tactile transfer devices arranged to transmit light from light-emitting devices and providing tactile feedback to a user.

### 2. DESCRIPTION OF RELATED ART

In the related art, along with development of multimedia, display apparatuses are growing in importance and also applied to apparatuses that embody virtual reality (VR), augmented reality (AR), and immersive extended reality (XR).

Display apparatuses (hereinafter, “tactile display apparatuses”) capable of expressing tactile sensations while displaying images are a very promising technology for immersive extended reality, and an interest in such tactile display apparatuses is also increasing.

Existing tactile display apparatuses have been used technologies that express the roughness of objects through, for example, electromagnetic waves, or the depths of images through actuators. However, reproduced tactile expressions are imperceptible or degrade image quality. For these reasons, a solution for a tactile display apparatus capable of expressing tactile information without affecting displayed images is being sought.

### SUMMARY

A tactile display apparatus capable of expressing tactile information is provided.

According to an aspect of the disclosure, a tactile display apparatus includes a display substrate including a plurality of pixels, wherein the plurality of pixels comprise light-emitting device regions, and the light-emitting device regions comprise light-emitting devices that are configured to operate based on image information; a plurality of tactile transfer devices positioned on the display substrate, wherein the plurality of tactile transfer devices are configured to adjust heights based on a control signal; and at least one lens mounted on the light-emitting device regions, wherein the plurality of tactile transfer devices are arranged not to block light from the light-emitting device in a state in which the plurality of tactile transfer devices are controlled to a maximum height.

The tactile display apparatus may include wherein each of the plurality of tactile transfer devices has an origami structure configured to adjust the height of which a height is adjusted by folding or unfolding the origami structure according to a control signal.

The tactile display apparatus may include wherein the plurality of tactile transfer devices are arranged without overlapping with the light-emitting device region.

The tactile display apparatus may include wherein a distance between the light-emitting device region and the at least one lens is equal to a front focal length of the lens.

The tactile display apparatus may include wherein at least two of the plurality of tactile transfer devices are positioned adjacent to each other, with the light-emitting device region positioned in between, wherein the two adjacent tactile transfer devices among the plurality of tactile transfer devices satisfy the following condition, 1/v≤(p+2r)/(2rh), wherein v is a rear focal length of the at least one lens, h is a maximum height of each of the at least two tactile transfer devices from a position of the at least one lens, r is a radius of the at least one lens, and p is a distance between the at least two tactile transfer devices.

The tactile display apparatus may include wherein the light-emitting device region comprises a red light-emitting device, a green light-emitting device, and a blue light-emitting device, and the rear focal length of the at least one lens is set based on blue light.

The tactile display apparatus may include wherein the light-emitting device region comprises a red light-emitting device, a green light-emitting device, and a blue light-emitting device.

The tactile display apparatus may include wherein the at least one lens comprises a first lens disposed on the red light-emitting device, a second lens arranged on the green light-emitting device, and a third lens arranged on the blue light-emitting device.

The tactile display apparatus may include wherein each of the plurality of tactile transfer devices comprises a flexible side wall having a shape forming an internal space, the side wall being flexible; and a cover covering the internal space.

The tactile display apparatus may include wherein each of the plurality of tactile transfer devices is positioned such that the light-emitting device region is positioned in the internal space.

The tactile display apparatus may include wherein a distance between the light-emitting device region and the at least one lens is a front focal length of the lens.

The tactile display apparatus may include wherein the tactile display apparatus satisfies the following condition, 1/v≤(p+2r)/(2rh), where v is a rear focal length of the at least one lens, h is a maximum height of each of the plurality of tactile transfer devices from a position of the at least one lens, r is a radius of the at least one lens, and p is a width of the internal space of each of the plurality of tactile transfer devices.

The tactile display apparatus may include wherein the light-emitting device region comprises a red light-emitting device, a green light-emitting device, and a blue light-emitting device, and a rear focal length of the at least one lens is determined based on blue light.

The tactile display apparatus may include wherein the at least one lens is a meta lens based on a nanostructure.

The tactile display apparatus may include wherein each of the plurality of tactile transfer devices is further configured to control at least one of a tilt, a restoring force, a movement speed, or a movement direction of the tactile transfer device.

A tactile display apparatus according to an embodiment may include a display substrate including a plurality of pixels PX. Each of the plurality of pixels may include a light-emitting device region ER. The light-emitting device region ER may include at least one light-emitting device that operates based on image information. On the display substrate, a plurality of tactile transfer devices TD each of whose height is adjusted according to a control signal may be provided. On the light-emitting device region ER, a lens may be arranged. The tactile transfer devices may be arranged not to block light from the light-emitting device in the state in which the plurality of tactile transfer devices are controlled to a maximum height.

The tactile display apparatus described above may precisely express a contact-type tactile sensation while displaying an image.

The tactile display apparatus described above may minimize image distortion caused by a tactile expression.

### BRIEF DESCRIPTION OF THE DRAWINGS

The above and other aspects, features, and advantages of certain embodiments of the present disclosure are more apparent from the following description taken in conjunction with the accompanying drawings, in which:

FIG. 1 is a block diagram showing a tactile display apparatus according to an embodiment.

FIG. 2 is a plan view showing a pixel configuration of a display apparatus according to a comparative example.

FIGS. 3A to 3D show examples of shape changes of a tactile transfer device that may be used in a tactile display apparatus according to an embodiment.

FIG. 4 is a plan view showing a pixel array of a tactile display apparatus according to an embodiment.

FIG. 5 is a plan view showing a pixel array of a tactile display apparatus according to an embodiment.

FIG. 6 is a plan view showing a pixel array of a tactile display apparatus according to an embodiment.

FIG. 7 is a plan view showing a pixel array of a tactile display apparatus according to an embodiment.

FIG. 8A is a cross-sectional view showing a pixel array of a tactile display apparatus according to an embodiment, and FIG. 8B is a plan view showing an arrangement relationship between light-emitting device regions and a lens in the tactile display apparatus of FIG. 8A.

FIG. 9 is an enlarged view of a part of the tactile display apparatus of FIG. 8A, conceptually showing that light from a light-emitting region is transmitted without being blocked by a tactile transfer device.

FIG. 10A is an enlarged cross-sectional view of a part of a tactile display apparatus according to an embodiment, and FIG. 10B is a plan view showing an arrangement relationship between light-emitting device regions and lenses in the tactile display apparatus of FIG. 10A.

FIG. 11 is an enlarged cross-sectional view of a part of a tactile display apparatus according to an embodiment.

FIG. 12 is an enlarged cross-sectional view of a part of a tactile display apparatus according to an embodiment.

FIGS. 13A to 13D show examples of shape changes of a tactile transfer device that may be used in a tactile display apparatus according to an embodiment.

FIG. 14 is a block diagram showing an electronic apparatus according to an embodiment.

### DETAILED DESCRIPTION

The embodiments described in the disclosure, and the configurations shown in the drawings, are only examples of embodiments, and various modifications may be made without departing from the scope and spirit of the disclosure.

Hereinafter, an embodiment of the disclosure will be described in detail with reference to the accompanying drawings so that the present disclosure may be readily implemented by one of ordinary skill in the technical field to which the present disclosure pertains. However, the present disclosure may be implemented in various different forms and is not limited to the embodiments described herein. Also, in the drawings, portions irrelevant to the description are not shown in order to definitely describe the present disclosure, and throughout the entire specification, similar parts are assigned like reference numerals.

In the entire specification, it will be understood that the case in which a certain portion is “connected” to another portion includes the case in which the portion is “electrically connected” to the other portion with another device in between, as well as the case in which the portion is “directly connected” to the other portion. Also, it will be understood that when a certain portion “includes” a certain component, the portion does not exclude another component but can further include another component, unless the context clearly dictates otherwise.

In addition, the terms “portion”, “part”, etc. used in this specification refer to a unit for processing at least one function or operation, which is implemented as hardware, software, or a combination of hardware and software.

Although general terms being currently widely used were selected as terminology used in the present disclosure while considering the functions of the present disclosure, they may change according to intentions of one of ordinary skill in the art, judicial precedents, the advent of new technologies, and the like. Also, terms arbitrarily selected by the applicant of the present disclosure may also be used in a specific case. In this case, their meanings will be described in detail in the description about the corresponding embodiment. Hence, the terms used in this specification must be defined based on the meanings of the terms and the contents of the entire specification, not by simply stating the terms themselves. The expressions “at least one of A, B and C” and “at least one of A, B, or C”, both indicate “A”, only “B”, only “C”, both “A and B”, both “A and C”, both “B and C”, and all of “A, B, and C”.

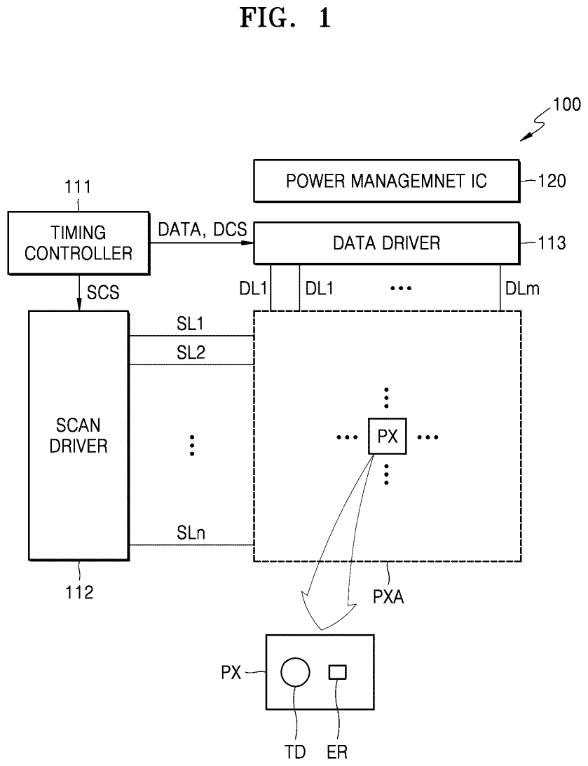

FIG. 1 is a block diagram showing a tactile display apparatus according to an embodiment.

Referring to FIG. 1, a tactile display apparatus 100 according to an embodiment may include a pixel array PXA including a plurality of pixels PX. The tactile display apparatus 100 may also include a timing controller 111, a scan driver 112, a data driver 113, and a power management IC (PMIC) 120. A circuit including at least one of the timing controller 111, the scan driver 112, or the data driver 113 may be referred to as a display driver IC (DDI). The display driver IC may be provided in the form of an integrated circuit.

The pixel array PXA may be positioned on a display substrate (not shown). On the display substrate, circuit elements for driving the pixel array PXA may be formed, and for example, at least a part of the timing controller 111, the scan driver 112, the data driver 113, or the power management IC (PMIC) 120 may be formed in the form of an integrated circuit.

Each of the plurality of pixels PX may include a light-emitting device region ER. The light-emitting device region ER may include at least one light-emitting device that is controlled according to image information. The light-emitting device may include a Light Emitting Diode (LED), a micro LED, an Organic LED (OLED), or an Active Matrix OLED (AMOLED). The light-emitting device region ER may include a red light-emitting device that emits red light, a green light-emitting device that emits green light, and a blue light-emitting device that emits blue light, which form a red sub-pixel, a green sub-pixel, and a blue sub-pixel. To form sub-pixels of different light colors, light-emitting devices that express, for example, white, cyan, magenta, or yellow may be provided.

The tactile display apparatus 100 according to an embodiment may transfer tactile information while displaying an image. To this end, the tactile display apparatus 100 may include a plurality of tactile transfer devices TD arranged on the display substrate. FIG. 1 conceptually shows a pixel (PX) array that transfers a tactile sensation while displaying an image. A width of a pixel (PX) region may be defined as a distance between neighboring light-emitting device regions ER, that is, a pixel pitch. A portion of a light-emitting device region ER in a pixel (PX) region may be very small. For example, the portion may be 10% or less, 5% or less, 3% or less, or 2% or less. A configuration in which a tactile transfer device TD and a light-emitting device region ER are included in a pixel PX may be only an example, and all the pixels PX are not limited to this configuration. For example, a part of the plurality of pixels PX may include only light-emitting device regions ER and another part may include tactile transfer devices TD and light-emitting device regions ER. Also, a plurality of tactile transfer devices TD may be included in a pixel PX, or the tactile transfer devices TD may be positioned at boundaries between pixels PX.

The plurality of pixels PX may be respectively connected to corresponding data lines and scan lines, and light-emitting devices included in the pixels PX may operate according to received signals.

The timing controller 111 may provide a data value DATA, a data control signal DCS, etc. for each frame to the data driver 113. The timing controller 111 may provide a clock signal, a scan control signal SCS, etc. to the scan driver 112.

The data driver 113 may generate data voltages that are provided to data lines DL1 to DLm by using a data value DATA and a data control signal DCS received from the timing controller 111, wherein m is a natural number.

The scan driver 112 may receive a scan control signal SCS (including a clock signal, a scan start signal, etc.) from the timing controller 111 and generate scan signals that are provided to scan lines SL1 to SLn, wherein n is a natural number.

The power management IC 120 may receive an external input voltage (e.g., a battery voltage). According to an example, the power management IC 120 may generate a voltage that is supplied to the display driver IC based on the external input voltage. The power management IC 120 may generate a voltage that is to be provided to the timing controller 111 of the display driver IC. The power management IC 120 may include at least one regulator. The regulator may generate output voltages having various voltage levels based on a voltage received from an external power source. The regulator may be formed as a controller or included in a controller. The regulator may include a buck-converter, a buck-boost converter, a boost converter, or a cuk converter.

A circuit for driving the plurality of tactile transfer devices TD may be integrated into the display driver IC or separated from the display driver IC. The plurality of tactile transfer devices TD may also be connected to data lines and scan lines and may operate according to tactile information related to an image.

In the tactile display apparatus 100 according to an embodiment, the plurality of tactile transfer devices TD may be arranged without overlapping with the light-emitting device regions ER. When seen from above an image display surface or in a plan view, the plurality of tactile transfer devices TD may be arranged without overlapping with the light-emitting device regions ER. The plurality of tactile transfer devices TD may be arranged not to block light from the light-emitting device regions ER.

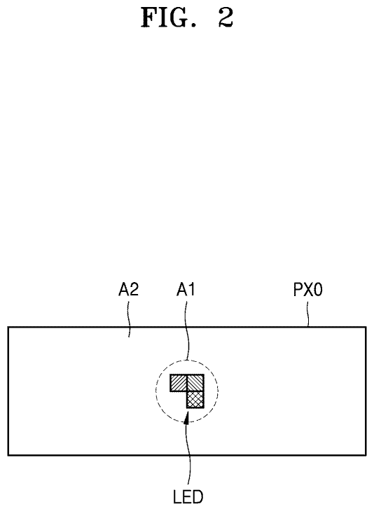

FIG. 2 is a plan view showing a pixel configuration of a display apparatus according to a comparative example.

The display apparatus according to the comparative example may be a micro LED display apparatus, and a single pixel is shown. That is, a plurality of pixels PX0 may be arranged two-dimensionally to form a pixel array. In the micro LED display apparatus, most of an area within a pixel PX may be an empty space. As shown, the area of the pixel PX may be divided into a first area A1 occupied by a LED and the remaining second area A2, and a portion of the area occupied by the LED in the pixel PX, that is, a fill factor may be very small. For example, in the case of a LED, a fill factor is about 11%, and in the cases of mini-LED and micro-LED, fill factors gradually decrease to almost 3% or less. Fill factors are gradually decreasing.

The tactile display apparatus 100 according to an embodiment may arrange the tactile transfer devices using the empty area to provide a contact-type tactile sensation that allows one to feel a realistic sense of touch, while minimizing influence of tactile expressions on image expressions.

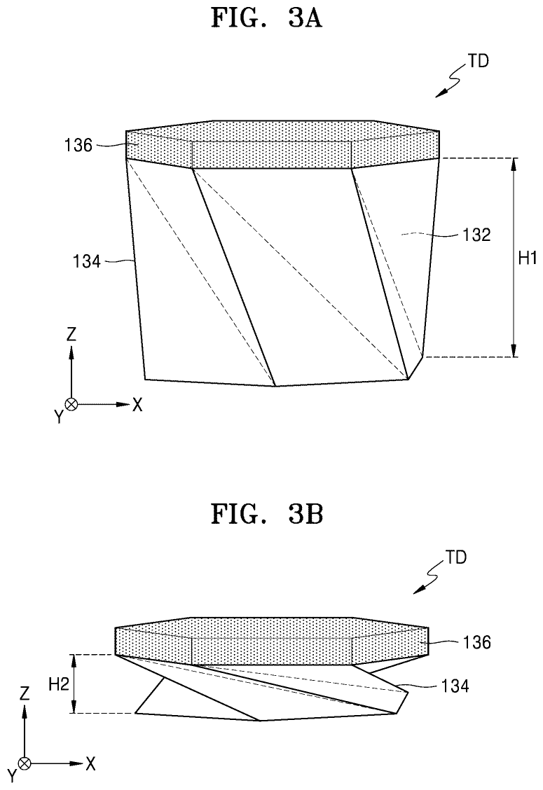

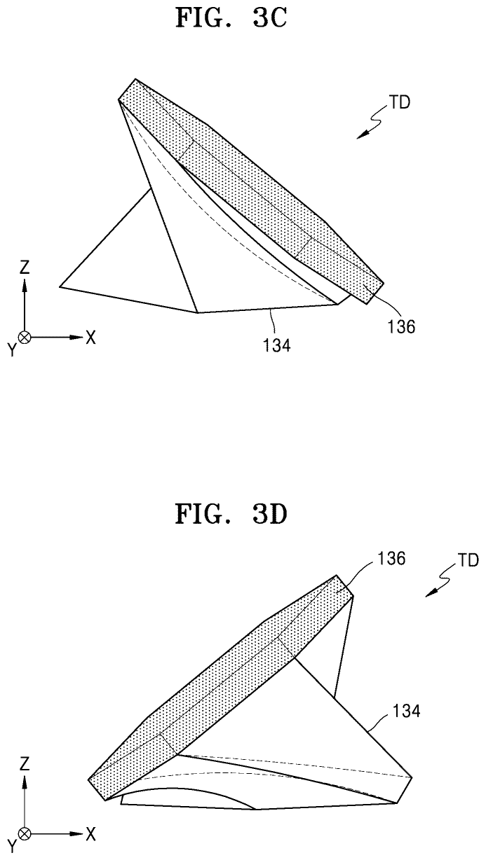

FIGS. 3A to 3D show examples of shape changes of a tactile transfer device that may be used in a tactile display apparatus according to an embodiment.

The tactile transfer device TD may be an origami structure of whose height is adjusted by being folded or unfolded according to a control signal. In addition to the height of the tactile transfer device TD, at least one of a tilt, a restoring force, or a movement speed of the tactile transfer device TD may be further controlled.

The tactile transfer device TD may be an origami cylinder. A control signal for controlling the tactile transfer device TD may be an electrical signal, a magnetic signal, or an electromagnetic signal.

The tactile transfer device TD may be, for example, a Kresling origami pattern structure using a magnetic field. However, the tactile transfer device TD is not limited thereto and may include various kinds of origami structures capable of expressing various tactile sensations by adjusting heights.

The tactile transfer device TD may include a side wall 134 made of a flexible material. The side wall 134 which is flexible may have a shape forming an internal space 132. The tactile transfer device TD may include a cover 136 that covers the internal space 132 formed by the side wall 134. The cover 136 is shown as being hexagonal and the side wall 134 is shown as having six sides. However, the present disclosure is not limited thereto and various other shapes are also possible. The cover 136 may be made of an optically transparent material, although not limited thereto. In the case in which the tactile transfer device TD is positioned not to block light from the light-emitting device region ER, a degree of freedom in selecting a material of the cover 136 may increase.

The side wall 134 may be folded by various methods. For example, as shown in FIGS. 3A and 3B, the side wall 134 included in the tactile transfer device TD may be folded and unfolded to implement different heights H1 and H2 without changing an arrangement angle of the cover 136. Alternatively, as shown in FIGS. 3C and 3D, both a height of the side wall 134 and an arrangement angle of the cover 136 may be adjusted.

By such deformation of the tactile transfer device TD, various surface roughness and hardness may be expressed. Surface roughness may be expressed by a height or tilt of the tactile transfer device TD, and hardness may be expressed by a restoring force of the tactile transfer device TD.

Additionally, the tactile transfer device TD may change in shape according to an applied control signal, and accordingly, there may be restrictions on selecting a material of the flexible side wall 134 operating in this manner to be optically transparent. In other words, the side wall 134 may be made of a material that blocks (absorbs or reflects) light, and in the case in which light from the light-emitting device region ER is blocked by the side wall 134, image quality may deteriorate. As described with reference to FIG. 1, because a portion of an area occupied by a light-emitting device region ER in a pixel (PX) region is very small, the tactile transfer device TD may be positioned to minimize such image quality deterioration. Hereinafter, various examples will be described.

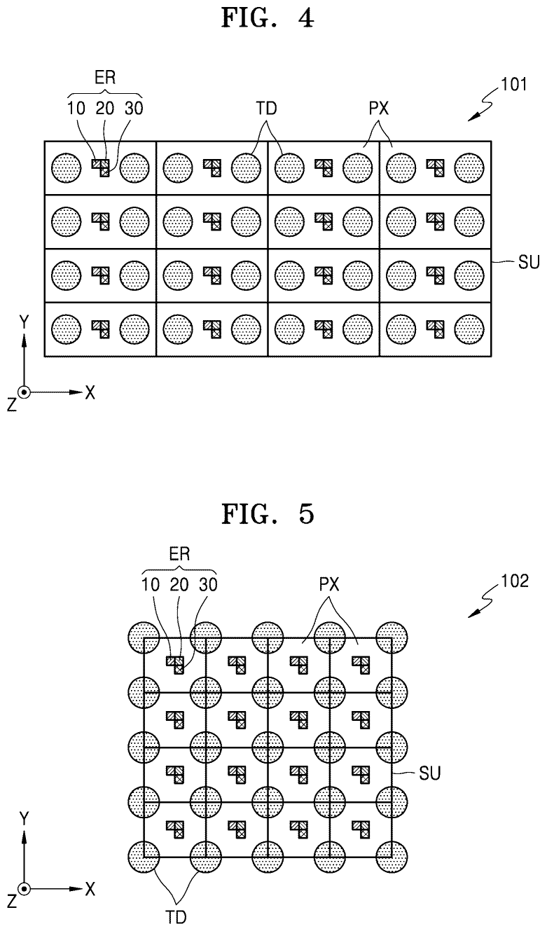

FIG. 4 is a plan view showing a pixel array of a tactile display apparatus according to an embodiment.

A tactile display apparatus 101 according to an embodiment may include a display substrate SU and a plurality of pixels PX. Each of the plurality of pixels PX may include a light-emitting device region ER, and two tactile transfer devices TD may be positioned with a light-emitting device region ER in between.

On the display substrate SU, at least a part of the display driver IC may be formed, and at least a part of a driving circuit for driving the tactile transfer devices TD may be formed.

The light-emitting device region ER may include a red light-emitting device 10, a green light-emitting device 20, and a blue light-emitting device 30. An arrangement of the red light-emitting device 10, the green light-emitting device 20, and the blue light-emitting device 30 may be an example, and another arrangement may be possible.

Each pixel PX may have a rectangular shape of which a length in an X direction is longer than a length in a Y direction, and in the pixel PX, two tactile transfer devices TD may be arranged in the X direction with a light-emitting device region ER in between. This may be an example, and an arrangement of the tactile transfer devices TD may change according to a shape of each pixel PX.

FIG. 5 is a plan view showing a pixel array of a tactile display apparatus according to an embodiment.

A tactile display apparatus 102 according to an embodiment may be different from the tactile display apparatus 101 of FIG. 4 in that a plurality of tactile transfer devices TD are respectively positioned at intersections of neighboring pixels PX. The plurality of tactile transfer devices TD included in the tactile display apparatus 102 may be arranged alternately with light-emitting device regions ER along one direction, for example, two diagonal directions of each pixel PX. The pixel PX is shown as having a shape close to a square. However, an arrangement of the tactile transfer devices TD according to some embodiment is not limited to being applied only to the shape of the pixel PX.

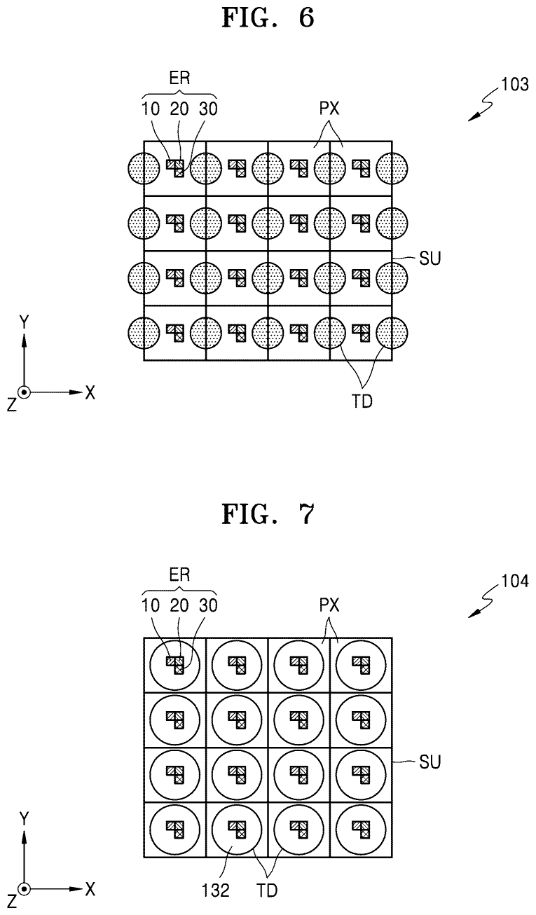

FIG. 6 is a plan view showing a pixel array of a tactile display apparatus according to an embodiment.

A plurality of tactile transfer devices TD included in a tactile display apparatus 103 may be respectively positioned at boundaries between pixels PX and arranged alternately with light-emitting device regions ER along one direction, for example, the X direction.

The arrangements of the tactile transfer devices TD of FIGS. 4 to 6 are examples, and various modifications may be possible. Also, in the respective embodiments, sizes and numbers of the tactile transfer devices TD may be set appropriately not to block light from the light-emitting device regions ER.

FIG. 7 is a plan view showing a pixel array of a tactile display apparatus according to an embodiment.

A tactile display apparatus 104 according to an embodiment may be different from the above-described embodiments in that each light-emitting device region ER is positioned in an internal space 132 of a tactile transfer device TD.

For convenience of expression, the cover 136 of the tactile transfer device TD illustrated in FIGS. 3A to 3D is omitted, and in some embodiment, the cover 136 may be made of a transparent material to transmit light from the light-emitting device region ER. A maximum height of the tactile transfer devices TD may be set to prevent light from the light-emitting device regions ER from arriving at inner sides of the tactile transfer devices TD as possible.

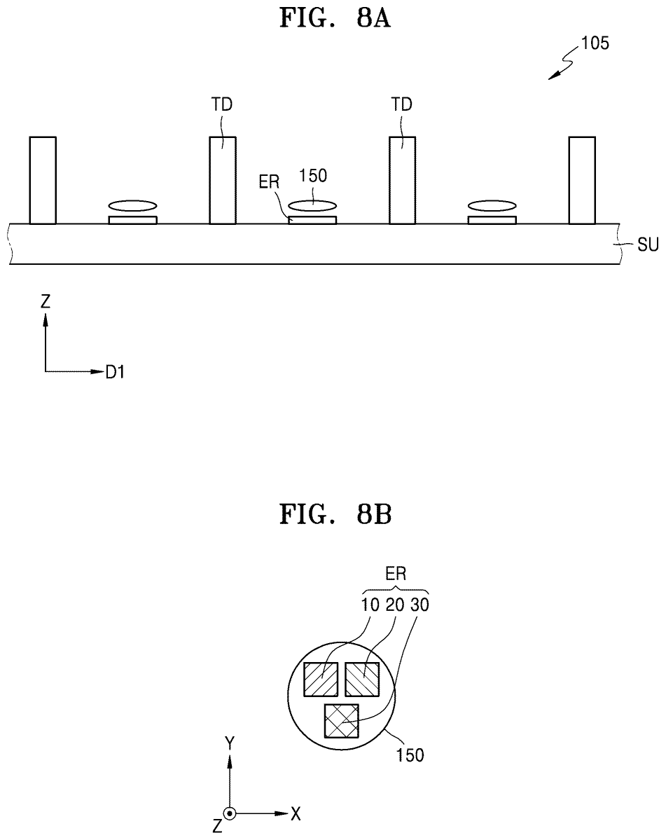

FIG. 8A is a cross-sectional view showing a pixel array of a tactile display apparatus according to an embodiment, and FIG. 8B is a plan view showing an arrangement relationship between light-emitting device regions and a lens in the tactile display apparatus of FIG. 8A.

A tactile display apparatus 105 may further include a lens 150 arranged on a light-emitting device region ER. This type including the lens 150 may also be applied to the embodiments described with reference to FIGS. 4 to 6. That is, a D1 direction denoted in the drawing may be the X direction, the Y direction, or the diagonal direction of each pixel.

The lens 150 may have a size that covers all of the red light-emitting device 10, the green light-emitting device 20, and the blue light-emitting device 30, as shown in FIG. 8B. However, this may be only an example, and a lens may be arranged on each of the red light-emitting device 10, the green light-emitting device 20, and the blue light-emitting device 30.

As such, by including the lens 150, details (for example, a focal length, an effective diameter, etc.) of the lens 150 and details (for example, a maximum height, an array spacing, etc.) of the tactile transfer device TD may be set such that an optical path on which light from the light-emitting device region ER is blocked by the tactile transfer device TD is not formed.

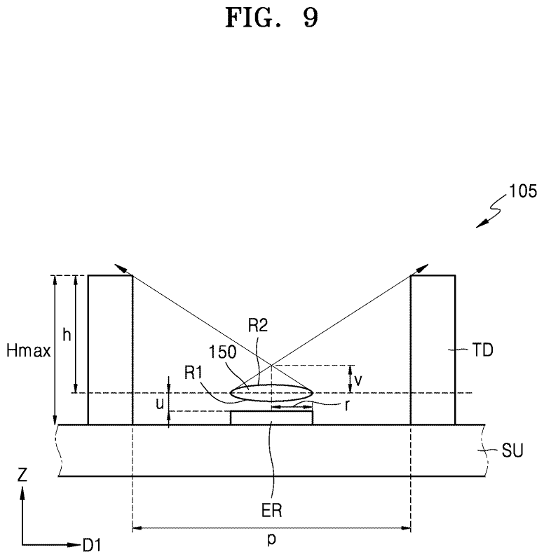

FIG. 9 is an enlarged view of a part of the tactile display apparatus of FIG. 8A, conceptually showing that light from a light-emitting region is transmitted without being blocked by a tactile transfer device.

In the drawing, u means a front focal length of the lens 150, that is, an incident-side focal length, and v means a rear focal length of the lens 150, that is, an exit-side focal distance. r is an effective radius of the lens, R1 is a radius of curvature of an incident surface of the lens 150, and R2 is a radius of curvature of an exit surface of the lens 150. p means a distance between two tactile transfer devices TD positioned adjacent to each other with a light emitting device region ER in between. Hmax is a maximum height in a range in which a height of the tactile transfer device TD changes, and h is a value indicating the maximum height Hmax from a position of the lens 150.

As shown, a distance between the light-emitting device region ER and the lens 150 may be set to the front focal length of the lens 150.

As shown, when light from the light-emitting device region ER is emitted within a range between light rays indicated by two arrows, the light may be prevented from being blocked by the tactile transfer devices TD.

This condition may be expressed by the following equation.

$$1 / v \leq ( p + 2 r ) / ( 2 rh ) \qquad [ Equation 1 ]$$

In other words, by setting radii of curvature R1 and R2 of two surfaces of the lens 150, a radius r, and a maximum height and array spacing of the tactile transfer devices TD to satisfy the condition, light from the light-emitting device region ER may be optimally prevented from being blocked by the tactile transfer devices TD.

Additionally, because a refractive index of the lens 150 depends on a wavelength of light, the lens 150 may have different focal lengths for red light, blue light, and green light. In an embodiment, as shown in FIG. 8B, because all of red light, blue light, and green light are incident to the lens 150, the front focal distance u and the rear focal length v may be set based on blue light to consider the above condition. The above equation may be transformed and expressed as follows.

$$( {A}^{′} + \frac{B}{{λ}_{\{ r , g , b \}}} ) ( \frac{1}{{R}_{1}} - \frac{1}{{R}_{2}} ) \leq \frac{p + 2 r}{2 r h} + \frac{1}{u} \qquad [ Equation 2 ]$$

λ_{r,g,b} collectively refers to wavelengths corresponding to red light, green light, and blue light, and the above equation may be satisfied for the three wavelengths.

In the embodiment in which all of red light, green light, and blue light are incident to the lens 150, when the above condition is set based on the wavelength of blue light, the above condition may also be satisfied for different wavelengths of light.

In the equation 2, A′ and B are constants related to a material of the lens 150, such as a refractive index. A′=A−1 and exemplary values of A and B are as follows.

TABLE 1

| Material | A | B |
|---|---|---|
| Fused silica | 1.4580 | 0.00354 |
| Borosilicate glass BK7 | 1.5046 | 0.00420 |
| Hard crown glass K5 | 1.5220 | 0.00459 |
| Barium crown glass BaK4 | 1.5690 | 0.00531 |
| Barium flint glass BaF10 | 1.6700 | 0.00743 |
| Dense flint glass SF10 | 1.7280 | 0.01342 |

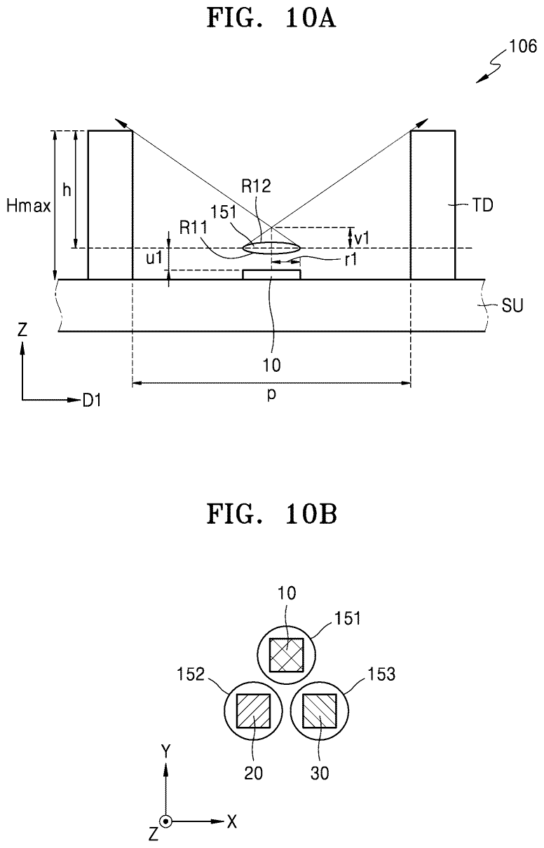

FIG. 10A is an enlarged cross-sectional view of a part of a tactile display apparatus according to an embodiment, and FIG. 10B is a top view showing an arrangement relationship between light-emitting device regions and lenses in the tactile display apparatus of FIG. 10A.

A tactile display apparatus 106 according to some embodiment may be different from the tactile display apparatus 105 described above in that a first lens 151 is mounted on the red light-emitting device 10, a second lens 152 is mounted on the green light-emitting device 20, and a third lens 153 is mounted on the blue light-emitting device 30.

A front focal length, a rear focal length, a radius, and two radii of curvature of the first lens 151 for red light are respectively represented as u1, v1, r1, R11, and R12. A distance between the first lens 151 and the red light-emitting device 10 may be set to the front focal length u1 of the first lens 151 for red light. Relationships of parameters u1, v1, r1, R11, and R12 of the first lens 151 and p, h, etc. of the tactile transfer device TD may be set according to the equations described above.

Although details of the second lens 152 and the third lens 153 are not separately shown, the second lens 152 and the third lens 153 may also be arranged in a similar way as described above, and also, a relationship with the tactile transfer devices TD may be set in a similar way as described above. That is, a distance between the second lens 152 and the green light-emitting device 20 may be set to a front focal length u2 of the second lens 152 for green light. Relationships of parameters u2, v2, r2, R21, and R22 of the second lens 20 (152) and p, h, etc. of the tactile transfer device TD may be set according to the equations described above. A distance between the third lens 153 and the blue light-emitting device 30 may be set to a front focal length u3 of the third lens 153 for blue light. Relationships of parameters u3, v3, r3, R31, and R32 of the third lens 153 and p, h, etc. of the tactile transfer device TD may be set according to the equations described above.

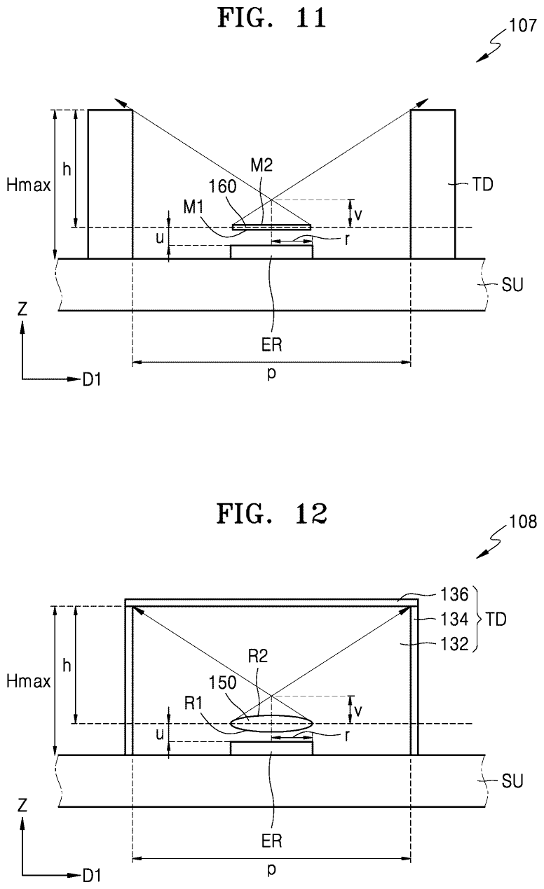

FIG. 11 is an enlarged cross-sectional view of a part of a tactile display apparatus according to an embodiment.

A tactile display apparatus 107 according to some embodiment may be different from the tactile display apparatus 105 described above in that a lens 160 arranged on the light-emitting device region ER is a meta lens. Meta lenses may be designed to exhibit desired lens performance by using nanostructures (not shown). Nanostructures having sub-wavelength shape dimensions may change the phase of light passing through the nanostructures by forming a refractive index difference distribution with the surrounding material, and form a preset, desired phase distribution. Such a phase distribution may be designed to be suitable for desired lens performance. Nanostructures may be formed on both surfaces M1 and M2 of the lens 160 or any one surface of the lens 160, and a detailed shape and arrangement of the nanostructures may be set to satisfy the equation 1 described above.

FIG. 12 is an enlarged cross-sectional view of a part of a tactile display apparatus according to an embodiment.

A tactile display apparatus 108 according to some embodiment may be different from the above-described embodiments in that the light-emitting device region ER is positioned in the internal space 132 of the tactile transfer device TD. The lens 150 may be positioned on the light-emitting device region ER and the lens 150 may also be positioned in the internal space 132.

Such a structure including the lens 150 may also be applied to the tactile display apparatus 104 described with reference to FIG. 7.

A relationship between the lens 150 and the tactile transfer device TD may satisfy the above-described equations, and in this case, p may be a width of the internal space 132, that is, a distance between inner surfaces of two side walls 134 facing each other in a D1 direction. D1 may be, but is not limited to, the X direction or the Y direction, or may be an arbitrary direction on an XY plane.

The lens 150 included in the tactile display apparatus 108 according to some embodiment may have a size that faces all of the red light-emitting device 10, the green light-emitting device 20, and the blue light-emitting device 30, as shown in FIG. 8B. Alternatively, similar to that described with reference to FIGS. 10A and 10B, the lens 150 may be configured with the first lens 151, the second lens 152, and the third lens 153 respectively positioned on the red light-emitting device 10, the green light-emitting device 20, and the blue light-emitting device 30. Also, the lens 150 may be a meta lens that is similar to the lens 160 described with reference to FIG. 11.

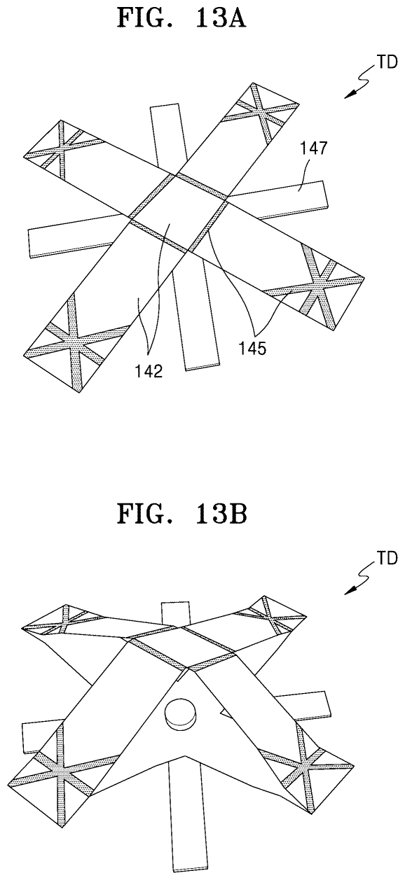

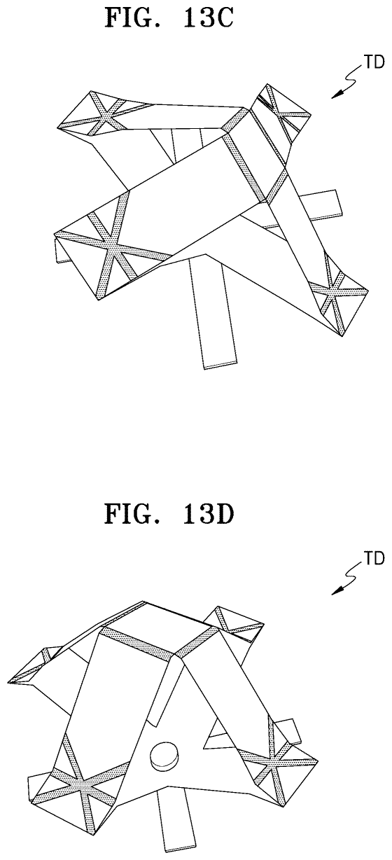

FIGS. 13A to 13D show examples of shape changes of a tactile transfer device that may be used in a tactile display apparatus according to an embodiment.

The tactile transfer device TD may be an origami structure of which a height or tilt changes. Referring to FIG. 13A, the tactile transfer device TD may have a shape including flexible parts 145, hard parts 142, and a plurality of driving shafts 147. The tactile transfer device TD may be subject to 1-axis driving as shown in FIG. 13B, 2-axis driving as shown in FIG. 13C, and 4-axis driving as shown in FIG. 13D, and accordingly, the flexible parts may be folded or unfolded to implement various heights and tilts. In addition to the height and tilt of the tactile transfer device TD, at least one of a restoring force, a movement speed, or a movement direction of the tactile transfer device TD may be further controlled.

The shown structure may be an example, and for example, the positions or number of the flexible parts 145 and the positions and number of the driving shafts 147 may change variously.

The tactile transfer device TD may be applied to the tactile display apparatuses 100, 101, 102, 103, 104, 106, and 107 described above.

In addition, different origami structures such as a cylinder type origami structure may be applied as the tactile transfer device TD to the tactile display apparatuses 100 to 108.

The tactile display apparatuses 100 to 108 according to the embodiments may be applied to various electronic apparatuses.

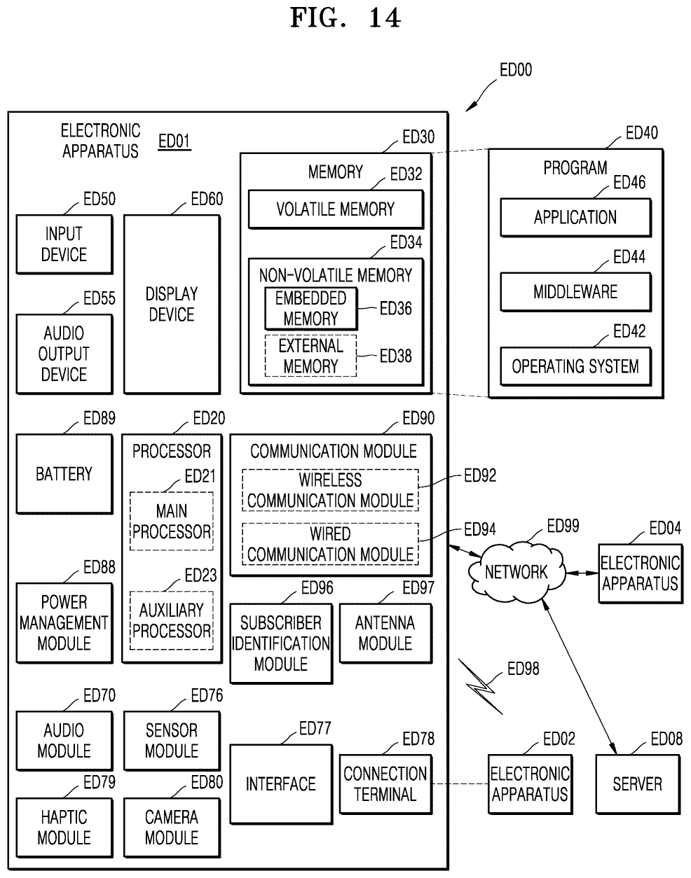

FIG. 14 is a block diagram showing an electronic apparatus according to an embodiment. Referring to FIG. 14, in a network environment ED00, an electronic apparatus ED01 may communicate with another electronic apparatus ED02 through a first network ED98 (a short-range wireless communication network, etc.), or communicate with still another electronic apparatus ED04 and/or a server ED08 through a second network ED99 (a long-distance wireless communication network, etc.). The electronic apparatus ED01 may communicate with the electronic apparatus ED04 through the server ED08. The electronic apparatus ED01 may include a processor ED20, memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic apparatus ED01, some (the display device ED60, etc.) of the components may be omitted or another component may be added. Some of the components may be implemented as a single integrated circuit. For example, the sensor module (a fingerprint sensor, an iris sensor, an illumination sensor, etc.) ED76 may be embedded into the display device (a display, etc.) ED60.

The processor ED20 may execute software (a program ED40, etc.) to control one or more other components (hardware, a software component, etc.) of the electronic apparatus ED01, connected to the processor ED20, and perform various data processing and calculations. As a part of the data processing and calculations, the processor ED20 may load a command and/or data received from another component (the sensor module ED76, the communication module ED90, etc.) in volatile memory ED32, process the command and/or data stored in the volatile memory ED32, and store resultant data in non-volatile memory ED34. The processor ED20 may include a main processor (a central processing unit, an application processor, etc.) ED21 and an auxiliary processor (a graphic processing unit, an image signal processor, a sensor hub processor, a communication processor, etc.) ED23 that may operate independently of or together with the main processor ED21. The auxiliary processor ED23 may consume less power than the main processor ED21 and perform specialized functions.

The auxiliary processor ED23 may control functions and/or states related to some (the display device ED60, the sensor module ED76, the communication module ED90, etc.) of the components of the electronic apparatus ED01, instead of the main processor ED21 while the main processor ED21 is in an inactive state (a sleep state) or together with the main processor ED21 while the main processor ED21 is in an active state (an application execution state). The auxiliary processor (an image signal processor, a communication processor, etc.) ED23 may also be implemented as a part of other functionally related components (the camera module ED80, the communication module ED90, etc.).

The memory ED30 may store various data required by components (the processor ED20, the sensor module ED76, etc.) of the electronic apparatus ED01. The data may include, for example, software (the program ED40, etc.) and input data and/or output data for commands related to the software. The memory ED30 may include the volatile memory ED32 and/or the non-volatile memory ED34.

The program ED40 may be stored as software in the memory ED30 and may include an operating system ED42, middleware ED44 and/or an application ED46.

The input device ED50 may receive commands and/or data to be used in components (the processor ED20, etc.) of the electronic apparatus ED01 from outside (a user, etc.) of the electronic apparatus ED01. The input device ED50 may include a microphone, a mouse, a keyboard, and/or a digital pen (a stylus pen, etc.).

The audio output device ED55 may output an audio signal to the outside of the electronic apparatus ED01. The audio output device ED55 may include a speaker and/or a receiver. The speaker may be used for general purposes such as playing multimedia or playback, and the receiver may be used to receive incoming calls. The receiver may be integrated into the speaker or implemented as an independent device.

The display device ED60 may visually provide information to the outside of the electronic apparatus ED01. The display device ED60 may include a display, a holographic device, or a projector and a control circuit for controlling the corresponding device. The display device ED60 may include touch circuitry configured to detect a touch, and/or sensor circuitry (a pressure sensor, etc.) configured to measure intensity of a force generated by a touch.

The display device ED60 may be a tactile display apparatus capable of transferring tactile information while displaying image information. For example, the display device ED60 may include any one or combination of the tactile display apparatuses 100 to 108 described above.

The audio module ED70 may convert sound into an electrical signal or convert an electrical signal into sound. The audio module ED70 may obtain sound through the input device ED50, or output sound through the audio output device ED55, and/or a speaker and/or headphone of another electronic apparatus (the electronic apparatus ED02, etc.) directly or wirelessly connected to the electronic apparatus ED01.

The sensor module ED76 may detect an operating status (power, temperature, etc.) of the electronic apparatus ED01 or an external environmental status (a user status, etc.) and generate an electrical signal and/or data value corresponding to the detected status. The sensor module ED76 may include a gesture sensor, a gyro sensor, an air pressure sensor, a magnetic sensor, an acceleration sensor, a grip sensor, a proximity sensor, a color sensor, an Infrared (IR) sensor, a biometric sensor, a temperature sensor, a humidity sensor, and/or an ambient light sensor.

The interface ED77 may support one or more designated protocols that may be used to directly or wirelessly connect the electronic apparatus ED01 to another electronic apparatus (the electronic apparatus ED02, etc.). The interface ED77 may include a High Definition Multimedia Interface (HDMI), a Universal Serial Bus (USB) interface, a Secure Digital (SD) card interface, and/or an audio interface.

The connection terminal ED78 may include a connector through which the electronic apparatus ED01 is physically connected to another electronic apparatus (the electronic apparatus ED02, etc.). The connection terminal ED78 may include an HDMI connector, a USB connector, an SD card connector, and/or an audio connector (a headphone connector, etc.).

The haptic module ED79 may convert an electrical signal into a mechanical stimulus (vibration, movement, etc.) or an electrical stimulus that a user may perceive through a tactile or kinesthetic sense. The haptic module ED79 may include a motor, a piezoelectric element, and/or an electrical stimulation device. The camera module ED80 may capture a still image and a moving image.

The camera module ED80 may include a lens assembly including one or more lenses, the image sensor 1000 described above, image signal processors, and/or flashes. The lens assembly included in the camera module ED80 may collect light emitted from a subject that is captured.

The power management module ED88 may manage power that is supplied to the electronic apparatus ED01. The power management module ED88 may be implemented as a part of a Power Management Integrated Circuit (PMIC).

The battery ED89 may supply power to the components of the electronic apparatus ED01. The battery ED89 may include a non-rechargeable primary battery, a rechargeable secondary battery and/or a fuel cell.

The communication module ED90 may support establishment of a direct (wired) communication channel and/or a wireless communication channel between the electronic apparatus ED01 and another electronic apparatus (the electronic apparatus ED02, the electronic apparatus ED04, the server ED08, etc.), and perform communication through the established communication channel. The communication module ED90 may operate independently of the processor ED20 (an application processor, etc.) and may include one or more communication processors that support direct communication and/or wireless communication. The communication module ED90 may include a wireless communication module (a cellular communication module, a short-range wireless communication module, a Global Navigation Satellite System (GNSS) communication module, etc.) ED92 and/or a wired communication module (a Local Area Network (LAN) communication module, a power line communication module, etc.) ED94. A corresponding one of the communication modules may communicate with another electronic apparatus through the first network (a short-range communication network, such as Bluetooth, Wireless-Fidelity (WiFi) Direct, or Infrared Data Association (IrDA)) ED98 or the second network (a long-range communication network, such as a cellular network, the Internet or a computer network (LAN, Wide Area Network (WAN), etc.)) ED99. These different types of communication modules may be integrated into a single component (a single chip, etc.) or implemented as a plurality of separate components (a plurality of chips). The wireless communication module ED92 may identify and authenticate the electronic apparatus ED01 within a communication network, such as the first network ED98 and/or the second network ED99, using subscriber information (an international mobile subscriber identity (IMSI), etc.) stored in the subscriber identification module ED96.

The antenna module ED97 may transmit a signal and/or power to or receive a signal and/or power from an external source (another electronic apparatus, etc.). An antenna may include a radiator formed of a conductive pattern on a substrate (a Printed Circuit Board (PCB), etc.). The antenna module ED97 may include one or a plurality of antennas. When a plurality of antennas are included, an antenna suitable for a communication method used in a communication network, such as the first network ED98 and/or the second network ED99, may be selected from among the plurality of antennas by the communication module ED90. A signal and/or power may be transmitted or received between the communication module ED90 and another electronic apparatus through the selected antenna. In addition to the antenna, another component (a Radio Frequency Integrated Circuit (RFIC), etc.) may be included as a part of the antenna module ED97.

Some of the components may be connected to each other and exchange a signal (a command, data, etc.) with each other through communication methods (a bus, General Purpose Input and Output (GPIO), a Serial Peripheral Interface (SPI), a Mobile Industry Processor Interface (MIPI), etc.) between peripheral devices.

A command or data may be transmitted or received between the electronic apparatus ED01 and the external electronic apparatus ED04 through the server ED08 connected to the second network ED99. The other electronic apparatuses ED02 and ED04 may be the same kind of apparatuses as the electronic apparatus ED01 or different kinds of apparatuses from the electronic apparatus ED01. All or a part of operations that are executed on the electronic apparatus ED01 may be executed by one or more of the other electronic apparatuses ED02, ED04, and ED08. For example, when the electronic apparatus ED01 needs to perform a certain function or service, the electronic apparatus ED01 may request one or more of the other electronic apparatuses to perform the entire or a part of the function or service, instead of itself executing the function or service. The one or more other electronic apparatuses that have received the request may execute an additional function or service related to the request and transmit the executed result to the electronic apparatus ED01. To this end, cloud computing, distributed computing, and/or client-server computing technologies may be utilized.

The tactile display apparatuses 100 to 108 described above may be implemented as wearable or non-wearable types and may be applied to various fields. For example, the tactile display apparatuses 100 to 108 may be utilized in combination with a general display apparatus, a television, a monitor, etc. and may be applied to various products, such as a mobile device, a automobile, a head-up display, an augmented/virtual/extended reality apparatus, a large signage, a wearable display, a rollable TV, and a stretchable display.

According to embodiments, there is provided a tactile display apparatus including: a display substrate including a plurality of pixels, wherein each of the plurality of pixels includes a light-emitting device region ER including at least one light-emitting device that operates according to image information; a plurality of tactile transfer devices TD positioned on the display substrate, wherein a height of each of the plurality of tactile transfer devices TD is adjusted according to a control signal; and a lens 150, 151, 152, 153, or 160 mounted on the light-emitting device region ER, wherein the plurality of tactile transfer devices TD are arranged not to block light from the light-emitting device in the state in which the plurality of tactile transfer devices TD are controlled to a maximum height.

Each of the plurality of tactile transfer devices TD may be an origami structure of which a height is adjusted by being folded or unfolded according to a control signal.

The plurality of tactile transfer devices TD may be arranged without overlapping with the light-emitting device region ER.

A distance between the light-emitting device region ER and the lens 150, 151, 152,153, or 160 may be a front focal length of the lens.

Two tactile transfer devices positioned adjacent to each other with the light-emitting device region in between among the plurality of tactile transfer devices TD may satisfy the following condition,

$$1 / v \leq ( p + 2 r ) / ( 2 rh ) ,$$

where v is a rear focal length of the lens, h is a maximum height of the tactile transfer device from a position of the lens, r is a radius of the lens, and p is a distance between the two tactile transfer devices.

The light-emitting device region ER may include a red light-emitting device 10, a green light-emitting device 20, and a blue light-emitting device 30, and the rear focal length of the lens may be set based on blue light.

The light-emitting device region may include a red light-emitting device, a green light-emitting device, and a blue light-emitting device.

The lens may include a first lens 151 mounted on the red light-emitting device, a second lens 152 mounted on the green light-emitting device, and a third lens 153 mounted on the blue light-emitting device.

Each of the plurality of tactile transfer devices TD may include a side wall 134 having a shape forming an internal space, the side wall 134 being flexible, and a cover 136 covering the internal space.

Each of the plurality of tactile transfer devices TD may be positioned such that the light-emitting device region ER is positioned in the internal space 132.

A distance between the light-emitting device region ER and the lens 150, 151, 153, or 160 may be a front focal length of the lens.

The tactile display apparatus may satisfy the following condition,

$$1 / v \leq ( p + 2 r ) / ( 2 rh ) ,$$

where v is a rear focal length of the lens, h is a maximum height of the tactile transfer device from a position of the lens, r is a radius of the lens, and p is a width of the internal space.

The light-emitting device region ER may include a red light-emitting device 10, a green light-emitting device 20, and a blue light-emitting device 30, and a rear focal length of the lens may be set based on blue light.

The lens 160 may be a meta lens based on a nanostructure.

At least one of a tilt, a restoring force, a movement speed, or a movement direction of the tactile transfer device may be further controlled.

The aforementioned descriptions of the present disclosure are only for illustrative purposes, and it will be understood by one of ordinary skill in the technical field to which the present disclosure belongs that the present disclosure can be easily modified to other detailed forms without changing the technical spirit or essential features of the present disclosure.

Thus, it should be understood that the embodiments described above are merely for illustrative purposes and not for limitation purposes in all aspects. For example, each component described as a single type can be implemented in a distributed type, and components described as distributed can be implemented in a combined form. Although the tactile display apparatuses have been described with reference to the embodiments shown in the drawings for easy understanding, these are only examples, and it will be understood by those of ordinary skill in the art that various modifications and other equivalent embodiments may be made from the embodiments.

Therefore, the disclosed embodiments should be considered from a descriptive standpoint rather than a restrictive standpoint. The scope of the present disclosure is defined in the accompanying claims rather than the above detailed description, and it should be noted that all differences falling within the claims and equivalents thereof are included in the scope of the present disclosure.

What is claimed is:

1. A tactile display apparatus comprising:
a display substrate including a plurality of pixels, wherein the plurality of pixels comprise light-emitting device regions, and the light-emitting device regions comprise light-emitting devices that are configured to operate based on image information;
a plurality of tactile transfer devices positioned on the display substrate, wherein the plurality of tactile transfer devices are configured to adjust heights based on a control signal; and
at least one lens mounted on the light-emitting device regions, wherein the plurality of tactile transfer devices are arranged not to block light from the light-emitting device in a state in which the plurality of tactile transfer devices are controlled to a maximum height.

2. The tactile display apparatus of claim 1, wherein
each of the plurality of tactile transfer devices comprises:
an origami structure of which a height of each of the plurality of tactile transfer devices is adjusted by folding or unfolding the origami structure based on a control signal.

3. The tactile display apparatus of claim 2, wherein
the plurality of tactile transfer devices are arranged not to overlap with the light-emitting device region.

4. The tactile display apparatus of claim 1, wherein
a distance between the light-emitting device region and the at least one lens is equal to a front focal length of the lens.

5. The tactile display apparatus of claim 1, wherein
at least two of the plurality of tactile transfer devices are positioned adjacent to each other, and have the light-emitting device region positioned therebetween,
wherein the two adjacent tactile transfer devices satisfy the following condition,
$$1 / v \leq ( p + 2 r ) / ( 2 rh ) ,$$
wherein v is a rear focal length of the at least one lens, h is a maximum height of each of the at least two tactile transfer devices from a position of the at least one lens, r is a radius of the at least one lens, and p is a distance between the at least two tactile transfer devices.

6. The tactile display apparatus of claim 5, wherein
the light-emitting device region comprises:
a red light-emitting device;
a green light-emitting device; and
a blue light-emitting device,
wherein the rear focal length of the at least one lens is determined based on blue light.

7. The tactile display apparatus of claim 1, wherein
the light-emitting device region comprises:
a red light-emitting device;
a green light-emitting device; and
a blue light-emitting device.

8. The tactile display apparatus of claim 7, wherein
the at least one lens comprises:
a first lens disposed on the red light-emitting device;
a second lens disposed on the green light-emitting device; and
a third lens disposed on the blue light-emitting device.

9. The tactile display apparatus of claim 1, wherein
each of the plurality of tactile transfer devices comprises:
a flexible side wall having a shape forming an internal space; and
a cover configured to cover the internal space.

10. The tactile display apparatus of claim 9, wherein
each of the plurality of tactile transfer devices is positioned such that the light-emitting device region is positioned in the internal space.

11. The tactile display apparatus of claim 10, wherein
a distance between the light-emitting device region and the at least one lens is equal to a front focal length of the lens.

12. The tactile display apparatus of claim 10, wherein
the tactile display apparatus satisfies the following condition,
$$1 / v \leq ( p + 2 r ) / ( 2 rh ) ,$$
wherein v is a rear focal length of the at least one lens, h is a maximum height of each of the plurality of tactile transfer devices from a position of the at least one lens, r is a radius of the at least one lens, and p is a width of the internal space of each of the plurality of tactile transfer devices.

13. The tactile display apparatus of claim 12, wherein
the light-emitting device region comprises:
a red light-emitting device;
a green light-emitting device; and
a blue light-emitting device,
wherein a rear focal length of the at least one lens is determined based on blue light.

14. The tactile display apparatus of claim 1, wherein
the at least one lens comprises a meta lens based on a nanostructure.

15. The tactile display apparatus of claim 1, wherein
each of the plurality of tactile transfer devices is further configured to control at least one of a tilt, a restoring force, a movement speed, or a movement direction of the each of the plurality of tactile transfer devices.
